(19) United States
(12) Patent Application Publication
(10) Pub. No.: US 2025/0012864 A1
(43) Pub. Date: Jan. 9, 2025

(54) BATTERY SEPARATORS AND METHODS FOR TESTING THE SAME

(71) Applicant: Celgard, LLC, Charlotte, NC (US)

(72) Inventors: Zhengming Zhang, Rock Hill, SC (US); Wenbin Yin, Charlotte, NC (US)

(21) Appl. No.: 18/709,529

(22) PCT Filed: Nov. 16, 2022
(86) PCT No.: PCT/US2022/050086

§ 371 Date: May 13, 2024

Related U.S. Application Data
(60) Provisional application No. 63/280,162, filed on Nov. 17, 2021.

(51) Int. Cl. G01R 31/385; G01N 13/00; G01R 31/389; H01M 50/403; H01M 50/417; H01M 50/491; H01M 50/497

(52) U.S. Cl. CPC G01R 31/3865; G01N 13/00; G01R 31/389; H01M 50/403; H01M 50/417; H01M 50/491; H01M 50/497

(57) ABSTRACT

Disclosed herein are new or improved method for measuring battery separators that are more suitable for modern battery separators and may more accurately predict performance in the battery. Also disclosed are characteristics of an ideal separator that may be measured according to the new or improved methods herein. The ideal separator may comprise one of more of the following properties: low electrical resistance (ER)/σᵢ approaching infinity; σₑ approaching zero when the separator is dry or wet with electrolyte; low or no volume (higher Wh/l); low or no weight (high Wh/kg); anti-compression (z-performance, wet); super strong (XYZ direction strength for processing when dry and wet); all temperature stability (mechanical, electrical, and electro-chemical when wet and dry); and ability to apply infinite force when measuring ISR.

### RELATED APPLICATION DATA

This Application is a 371 U.S. Application which claims priority to PCT Application No. PCT/US2022/050086, filed Nov. 16, 2022, which claims priority to U.S. Provisional Application No. 63/280,162, which was filed on Nov. 17, 2021, and is incorporated herein in its entirety.

### FIELD

This application relates new or improved battery separators, testing methods, and measurement or testing equipment, demo, setup, and the like for testing or measuring battery separators that may better predict performance in the battery, such as a lithium ion battery. The application also relates to properties of an ideal battery separator.

### BACKGROUND

A battery is a device that converts chemical energy into electrical energy. The positive electrode or cathode is a component of a battery. It accepts electrons from an external circuit, or is reduced. The negative electrode or anode is another component of a battery. It gives electrons to an external circuit, i.e., is oxidized. The separator is another component. It prevents the electrodes from touching and yet allows ions to pass between the electrodes in the battery.

Functions of battery separators include, but are not limited to, providing separation between anodes and cathodes. This is an important function. It is estimated that more than 90% of battery safety incidents are linked to internal shorts, which occur when dendrites are allowed to grow from the anode to the cathode across the separator. Separators must allow for the flow of ions across the battery separator during normal battery charge and discharge cycles. For polymeric separators, typically these need to be wet with liquid electrolyte to allow for ionic conduction. Once the battery separator is provided into the battery and is fully wet or wet out with electrolyte, no air flows across the separator. Once the separator is fully wet with electrolyte, there also is not typically any flow of liquid electrolyte, especially in a lithium ion battery. Battery separators should also be chemically and electronically stable, i.e., not reactive or minimally reactive with other components in the battery like the electrolyte and the electrode materials. In addition to this, industry desires thinner separators to improve energy density of the battery, better fit, safer, and ability to be used in automated battery production lines.

Historically, separator tests were linked to those used in the textile industry, and measurements used in that industry. One example of this is the Gurley measurement often done by those in the battery separator industry. Gurley is a measurement of air permeability. Air permeability testing is intended to assess a separator's resistance to the passage of air under a specified pressure. Testing typically follows the test method detailed in ASTM D726. Air permeability measures the air flow and it follows aerodynamics. However, there typically is no air or liquid electrolyte flow once the separator is placed in the Li-ion battery and wet with electrolyte.

Another typical test performed on battery separators is a wettability test. Wettability testing measures the time required for separator material to become completely wetted when it comes in contact with liquid electrolyte. Typical testing and measurements specific are described in NASA/TM 2010-216099. These measurements are typically done in air, and do not reflect conditions the battery separator will encounter in a battery. In the battery, factors such as the multi-phase interfaces (the components in electrolyte, cathode, anode, separator, vacuumed residue air, etc.) and the electrolyte injection process (vacuum level, vacuum times, amount of electrolyte/injection, sitting times etc.) will affect performance. In the battery, a vacuum is typically provided at least to some level and for some amount of time. Thus, any wetting tests done in the air, which can affect the surface energy of the separator, may not accurately reflect how the battery separator will perform in the battery.

A final typical test performed on battery separators is a puncture strength test. It is typically used as one indicator to predict a battery separators ability to resist internal shorting. However, this test may not reflect the conditions that a battery separator will experience once it is placed in the battery. For example, the separator is unsupported in the typical puncture strength test, but in the battery, the cathode and anode provide support. Thus, the typical test may not accurately reflect true battery performance. At least because internal shorting is believed to be the cause of more than 90% of safety incidents related to lithium ion batteries, a better test is needed.

As shown above, a need exists for battery separator tests whose results will better reflect actual or true battery performance. Tests typically used and linked to the textile industry may not be sufficient for the modern battery separator.

### SUMMARY

The inventions or embodiments described herein provide solutions for some or all of the problems described above.

In one embodiment, a complex method for testing battery separator performance is described. The method is complex because one, but preferably more than one, measurement is taken to determine battery separator performance and suitability for use in a lithium-ion battery. One measurement that could be taken is to measure the ionic conduction of the battery separator. Another measurement that could be taken is to measure the wettability of the battery separator under vacuum. Another measurement that could be taken is to measure the internal short resistance (ISR) of the battery separator. Another measurement that could be taken is to measure the wettability of the battery separator while being squeezed. Another measurement that could be taken is to measure the tension strength of the separator using a puncture strength test.

In one aspect, the complex method involves measuring the ISR of the battery separator. Measuring the ISR may involve measuring the ISR in any one of an x-direction of the separator, a y-direction of the separator, a z-direction of the separator, or combinations thereof.

In some embodiments, when testing ISR, a squeeze electrode device, demo, example, or setup is prepared. The squeeze electrode demo includes the separator, and in some embodiments, the squeeze electrode demo is tested. The squeeze electrode demo may preferably be selected from the following: cathode-material layer/separator/cathode-material layer; anode-material layer/separator/anode-material layer; anode-material layer/separator/cathode-material layer; Copper or Cu-foil/separator/aluminum or Al-foil; Al-foil/separator/Cu-foil; Cu-foil/separator/Cu-foil; Cu-mesh/separator/Cu mesh; Al-mesh/separator/Al mesh; Cu particles/separator/Cu particles; and Al particles/separator/Al particles.

In another aspect, the separator may be a porous polymeric separator. It may be a microporous polyolefin battery separator. The porous polymeric separator may be made from a wet-process or a dry-process. If a dry-process porous polymeric separator is used, the pores of the dry-process porous polymeric separator may be formed with or without the use of particles.

In another embodiment, an ideal separator is disclosed. An ideal separator may preferably comprise one or more of the following properties: low electrical resistance (ER)/σᵢ approaching infinity; σₑ approaching zero when the separator is dry or wet with electrolyte; low or no volume (higher Wh/l); low or no weight (high Wh/kg); anti-compression (z-performance, wet); super strong (XYZ direction strength for processing when dry and wet); all temperature stability (mechanical, electrical, and electro-chemical when wet and dry); and ability to apply infinite force when measuring ISR.

The ideal separator may be a porous polymeric separator. It may be a microporous polyolefin battery separator. The porous polymeric separator may be made from a wet-process or a dry-process. If a dry-process porous polymeric separator is used, the pores of the dry-process porous polymeric separator may be formed with or without the use of particles.

### BRIEF DESCRIPTION OF THE DRAWINGS

FIG. 1 is a schematic view of a battery as described herein comprising a positive electrode (“positive”), a negative electrode (“negative”), a separator, an electrolyte, and a circuit.

FIG. 2 is a schematic drawing of a laminate of an anode/separator/cathode for use in a battery, showing electrolyte in the interstices, pores, etc. and showing interfaces between the electrodes and the separator.

FIG. 3 explains the correlation of ionic hopping (i.e., conduction), not air flow or liquid flow, in lithium ion batteries, including those with liquid electrolyte, gel or polymer electrolyte, and solid state electrolyte.

FIG. 4 shows separator/air/holes interactions for typical contact angle wetting test.

FIG. 5 is an apparatus for wetting and testing ionic conduction.

FIG. 6 is a graph showing resistance (R) at different wetting times (t) for embodiments where low, medium, and high vacuum levels are used.

FIG. 7 is a schematic of finding the right frequency to monitor R*(1-3 kHz).

FIG. 8 is a graph of resistance (R) for different separator layer thickness for samples with certain R* values.

FIG. 9 is a schematic drawing of a classic film puncture strength measurement.

FIG. 10 is a schematic view of a classic film puncture strength measurement showing a view of the puncture pin puncturing the separator held by the O-ring. When punctured, there is no counterforce in the Z-direction from another object.

FIG. 11 is a schematic view showing separator tension created in a classic film puncture strength test. The classic puncture test is actually a film tension strength test.

FIG. 12 is a schematic drawing of a test device or setup for measuring internal short resistance (ISR) according to some embodiments described herein.

FIG. 13 is a schematic view of the squeeze electrode demo or example of the ISR test or measurement according to some embodiments described herein. Unlike the classic film puncture test, a counter force to the puncture force is provided.

FIG. 14 is a graph of ISR (kg) for a ½ inch ball for different sample numbers.

FIG. 15 is a graph showing a relationship between ball size and the force applied to the ball for exemplary battery separators and the ideal separator. Force applied increases with increasing ball size. For an ideal separator, force applied is or approaches infinity regardless of ball size.

FIG. 16 is a schematic diagram showing ionic flux through an anode (A), separator, and cathode (C) in a battery.

### DETAILED DESCRIPTION

Accordingly, embodiments, aspects, or objects described herein can be understood more readily by reference to the following detailed description, examples, and figures. Elements, apparatus, and methods described herein, however, are not limited to the specific embodiments presented in the detailed description, examples, and figures. It should be recognized that the exemplary embodiments herein are merely illustrative of the principles of the invention. Numerous modifications and adaptations will be readily apparent to those of skill in the art without departing from the spirit and scope of the invention.

In addition, all ranges disclosed herein are to be understood to encompass any and all subranges subsumed therein. For example, a stated range of “1.0 to 10.0” should be considered to include any and all subranges beginning with a minimum value of 1.0 or more and ending with a maximum value of 10.0 or less, e.g., 1.0 to 5.3, or 4.7 to 10.0, or 3.6 to 7.9.

All ranges disclosed herein are also to be considered to include the end points of the range, unless expressly stated otherwise. For example, a range of “between 5 and 10” or “5 to 10” or “5-10” should generally be considered to include the end points 5 and 10.

Further, when the phrase “up to” is used in connection with an amount or quantity; it is to be understood that the amount is at least a detectable amount or quantity. For example, a material present in an amount “up to” a specified amount can be present from a detectable amount and up to and including the specified amount.

Additionally, in any disclosed embodiment, the terms “substantially,” “approximately,” and “about” may be substituted with “within [a percentage] of” what is specified, where the percentage includes 0.1, 1, 5, and 10 percent.

Many different arrangements of the various components and/or steps depicted and described, as well as those not shown, are possible without departing from the scope of the claims below. Embodiments of the present technology have been described with the intent to be illustrative rather than restrictive. Alternative embodiments will become apparent from reference to this disclosure. Alternative means of implementing the aforementioned can be completed without departing from the scope of the claims below. Certain features and subcombinations are of utility and can be employed without reference to other features and subcombinations and are contemplated within the scope of the claims.

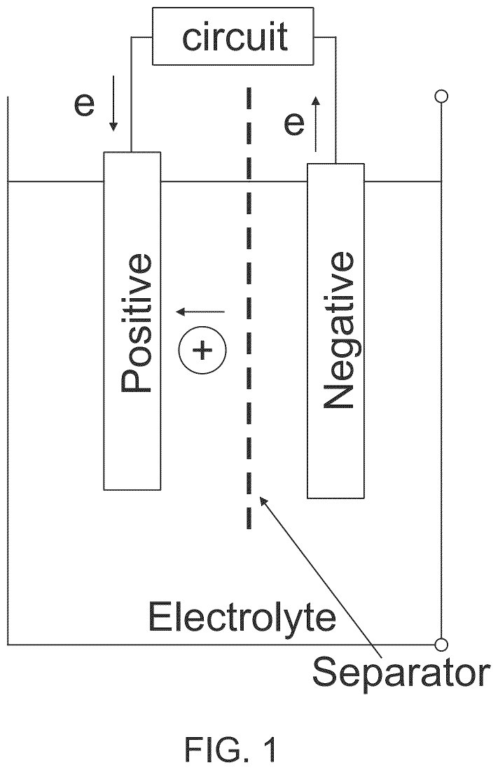

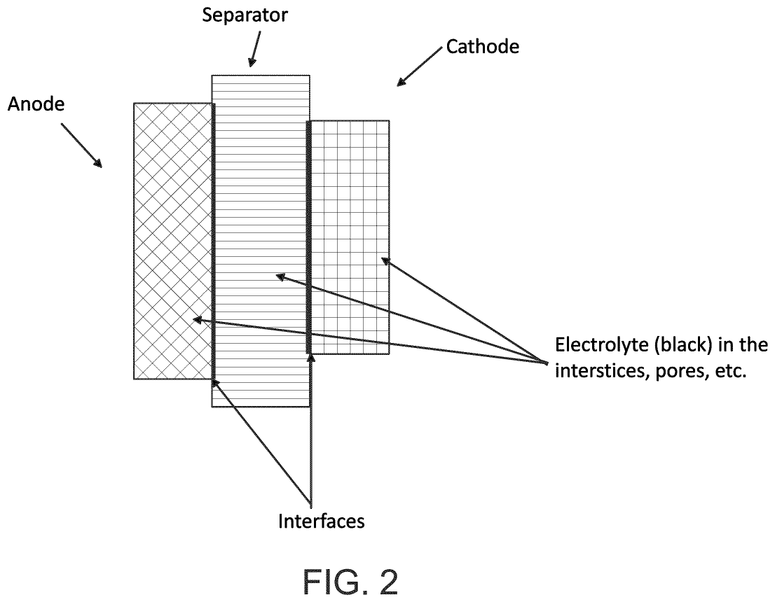

In a battery, e.g., a lithium ion battery, the separator provides separation between the negative electrode (anode) and the positive electrode (cathode), while still allowing ions to flow between the anode and the cathode. This is shown schematically in FIG. 1. Typically, a polymeric battery separator is not ionically conductive until it is wet with electrolyte. FIG. 2 is a schematic drawing of a composite including an anode, a separator, and a cathode, in that order.

The composite is wet with electrolyte, and electrolyte can be observed in the pores and interstices of the anode, the cathode, and the separator. Interfaces between the anode and the separator and between the cathode and the separator are also shown.

### Complex Method

The separator measurements described herein much better fit modern battery separators compared to prior methods that came from the textile industry. The complex method described herein is a set of one or more, two or more, three or more, or four or more measurements that should be done to evaluate a battery separator. The measurements described herein more closely mimic the conditions, environment, etc. that a battery separator will experience when it is in the battery, particularly a lithium-ion battery. The complex method described herein may comprise, consist of, or consist essentially of one or more of the following measurement steps: measuring the ionic conduction of the separator; measuring the wettability of the separator under vacuum; measuring internal short resistance (ISR) of the separator; measuring tension strength using a puncture strength test; and, measuring the wettability of the separator while being squeezed.

### Measuring Ionic Conduction

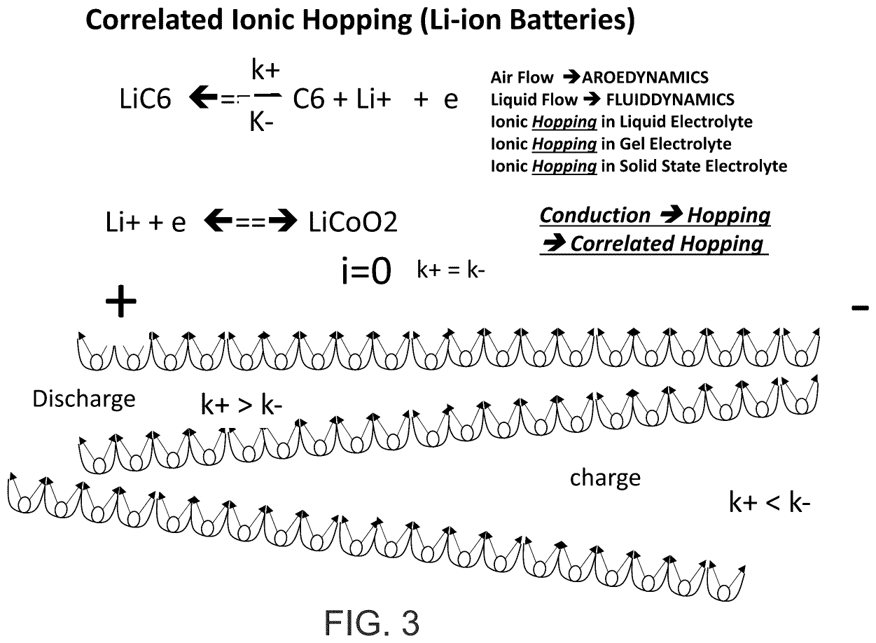

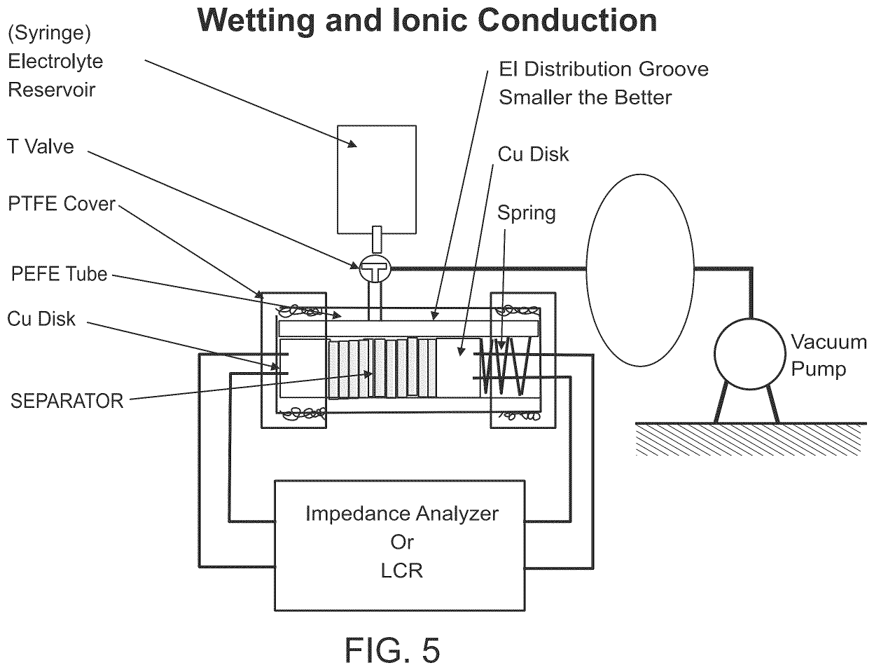

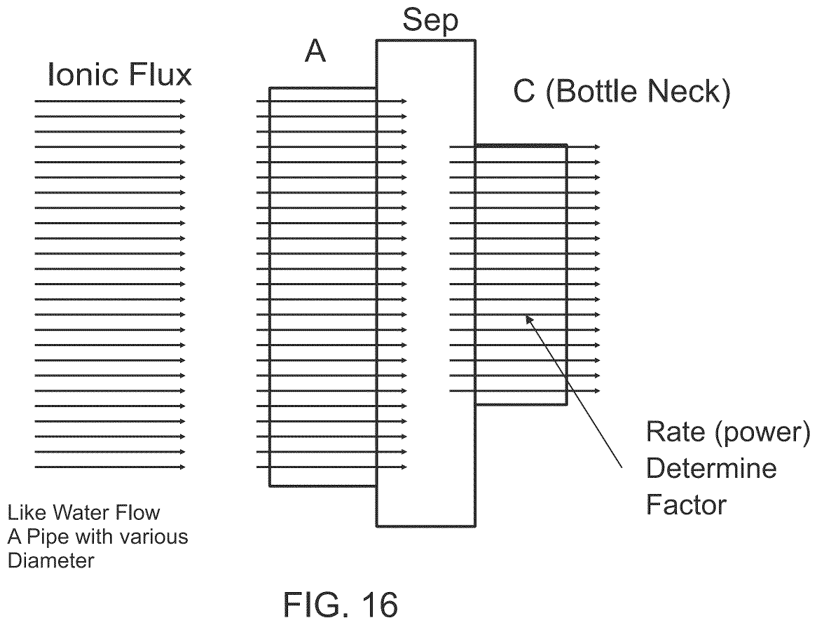

In some embodiments, the complex method may comprise measuring ionic conduction as the only measurement step or one of many measurement steps. A current test conducted on separators is the Gurley(s) measurement, which measures air flow across the separator. Air flow relates to aerodynamics as explained in FIG. 3, and there is no air flow across the separator in a lithium ion battery. The pores of the separator are filled with electrolyte. There also is not any or is minimal liquid flow across the separator, so a liquid flow/fluid dynamics measurement would not be appropriate. The real “flow” in the separator of batteries, is the correlated ionic conduction in soaked liquid electrolyte or solid state electrolyte, i.e., ionic conduction. Its measurement is called ionic conductivity that is not related with air permeability for modern popular separators such as ceramic coated separators. Thus, an appropriate measurement would be an ion hopping (i.e., conduction) measurement. This is shown and explained in FIG. 3. FIG. 5 herein shows an exemplary apparatus for measuring wetting and ionic conduction as described herein. FIG. 16 shows ionic flux in a lithium battery, and a bottle neck created at the cathode (C). In a typical battery, the separator is typically larger than either of the electrodes to make sure that the electrodes are not exposed if the separator were to shrink.

### Measuring Wettability Under Vacuum

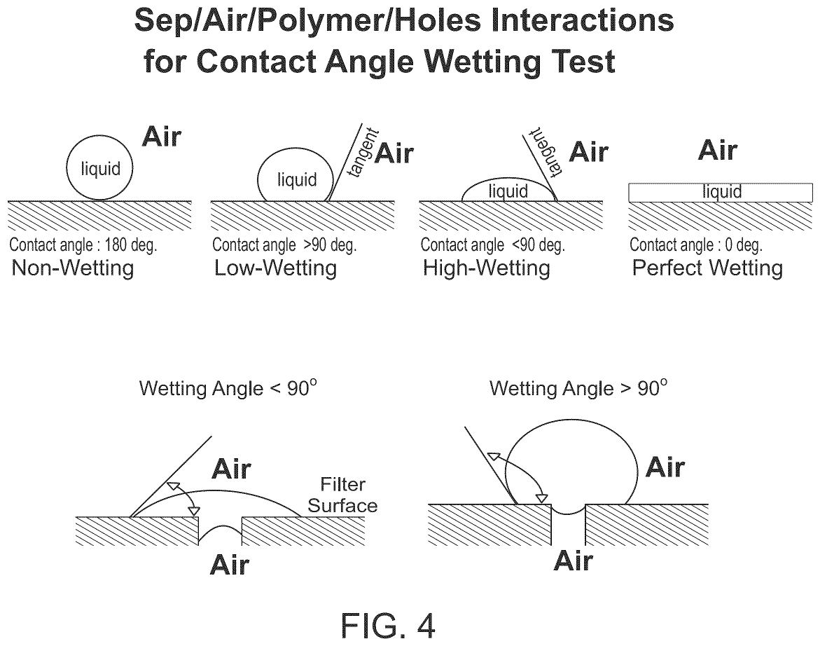

In some embodiments, the complex method may comprise measuring wettability of the separator under vacuum as the only measurement step or one of many measurement steps. Typical or classic wetting measurements are done in the air, i.e., not under vacuum. As shown in FIG. 4, interactions between the separator and air, interactions between the polymer of the separator and air, and interactions with air in the pores of the separator may affect the wettability measurements. Further, it should be noted that in a typical battery manufacturing process, wetting occurs under vacuum. Electrolyte is added under vacuum. Thus, a more appropriate wetting test should be performed under low, medium, or high vacuum to more closely simulate the conditions in the battery and more accurately predict wettability in the battery.

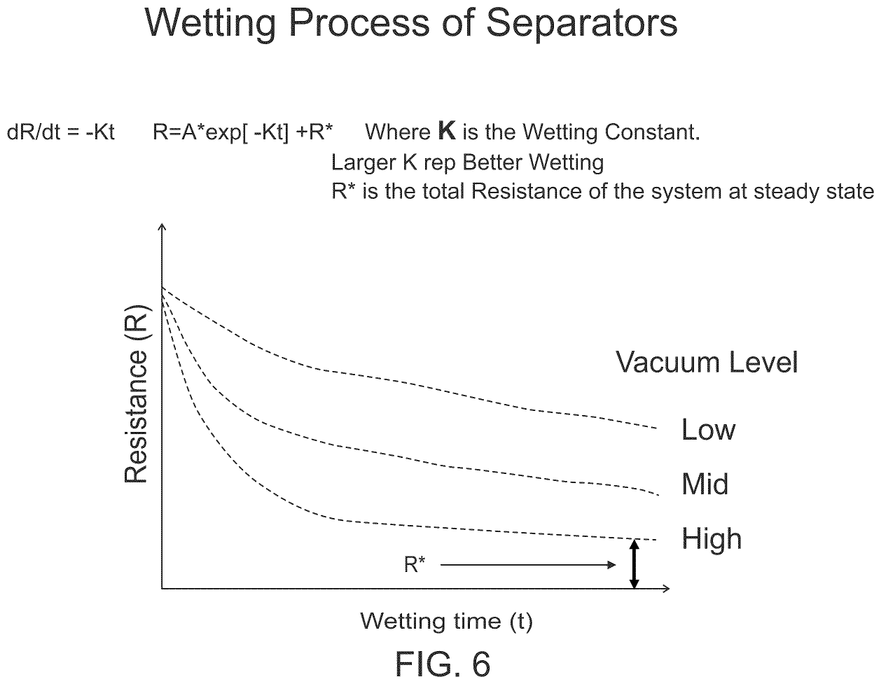

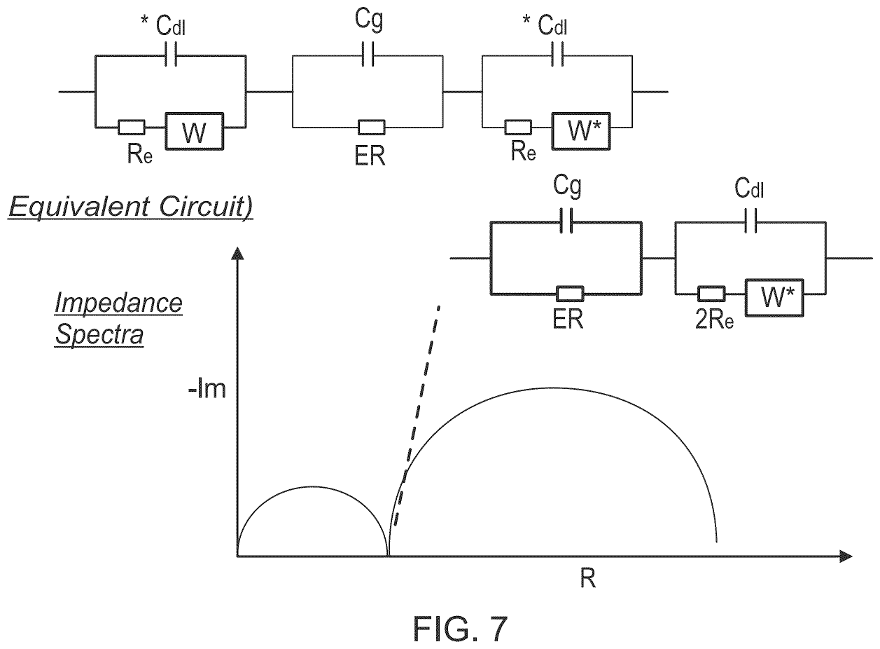

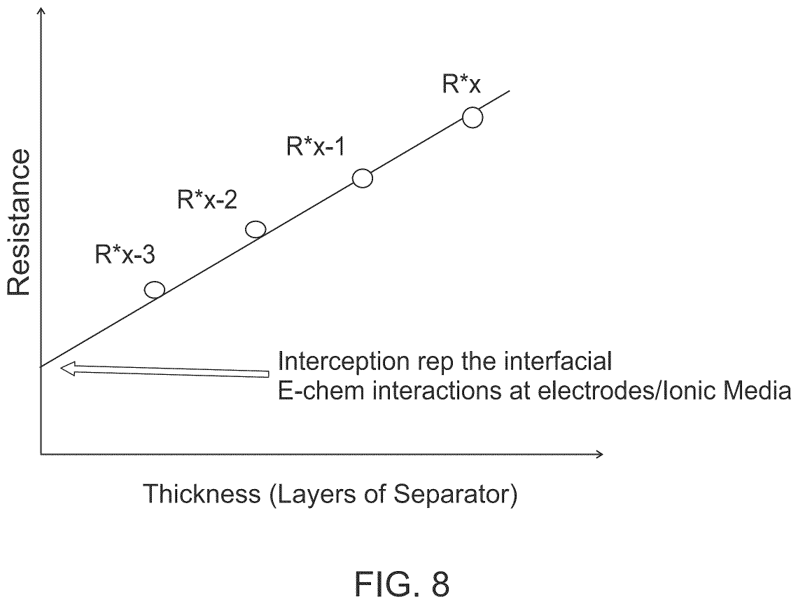

FIG. 5 herein shows an exemplary apparatus for measuring wetting and ionic conduction as described herein. FIG. 6 herein is a graph showing Resistance (R) as a function of wetting time (t) when a low, medium, and high vacuum are used. The high vacuum results in lower resistance, while the low vacuum results in the highest resistance of the three vacuum levels. FIG. 7 is a schematic of finding the right frequency to monitor resistance (R*), which may be from 1-3 kHz. FIG. 8 shows resistance as a function of thickness (layers of separator). Resistance increases with increasing thickness.

### Measuring Internal Short Resistance (ISR) of the Separator

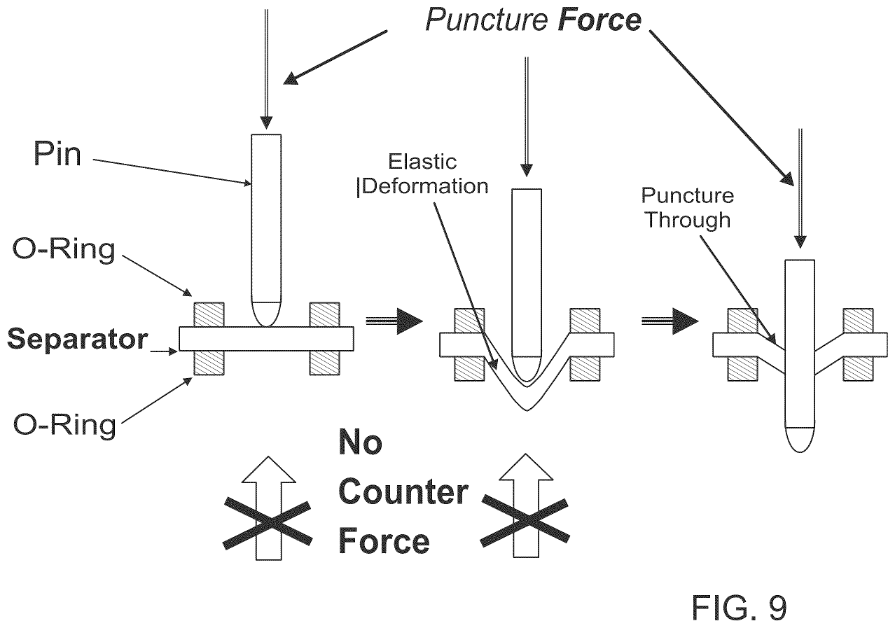

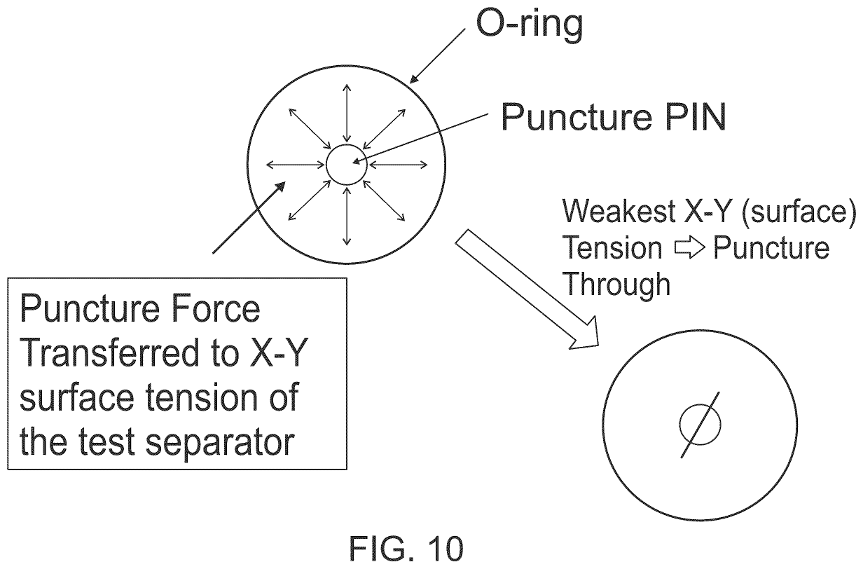

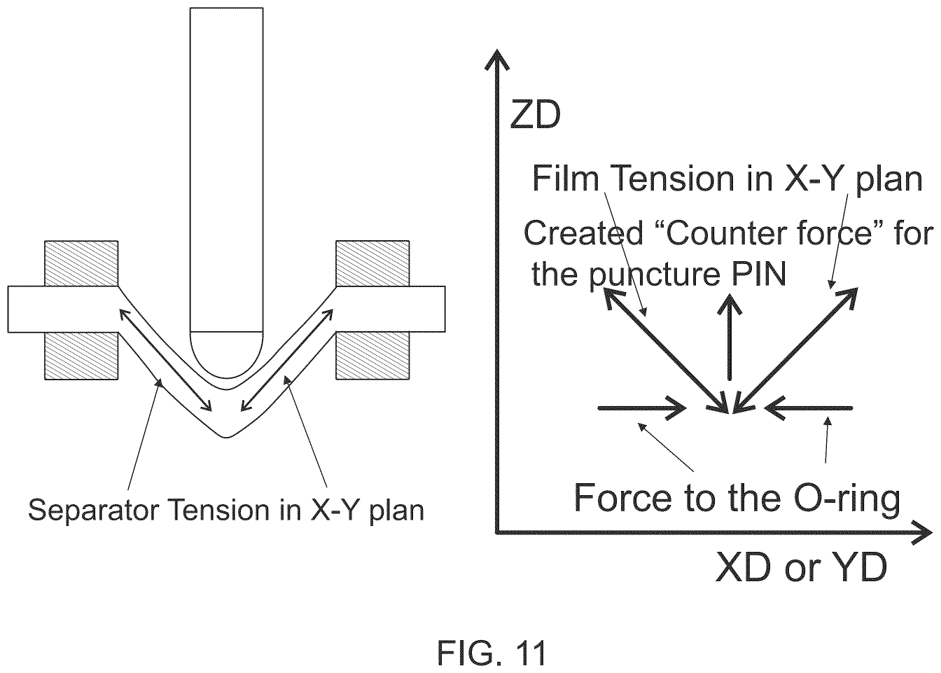

In some embodiments, the complex method may comprise measuring internal short resistance (ISR) as the only measurement step or one of many measurement steps. As explained above, a puncture strength test is typically used as one indicator to predict a battery separators ability to resist internal shorting. It is important to be able to predict a separators ability to resist internal shorting because over 90% of safety incidents in lithium ion batteries are believed to be a result or internal shorts. However, the puncture test may be an inadequate test because it does not well simulate the real conditions, environment, etc. that a separator experiences in a lithium ion battery. FIG. 9 is a schematic drawing of a classic film puncture strength measurement showing what may be its deficiencies. For example, as shown, there is no direct counter force to the puncture force. The separator is left exposed and unsupported by itself in the center of the O-Ring. FIG. 10 shows a view of the O-Ring in a classic film puncture strength measurement. It shows that, because there is no direct counter-force, puncture force is transferred to x-y surface tension of the tested separator, which may be weak. FIG. 11 shows that film tension in the x-y plane creates a counter force (not direct) to the puncture force. The classic film puncture strength measurement because, in the battery, the separator is sandwiched between two electrodes and thus supported on both side. It is not by itself and unsupported as in the classic film puncture strength measurement.

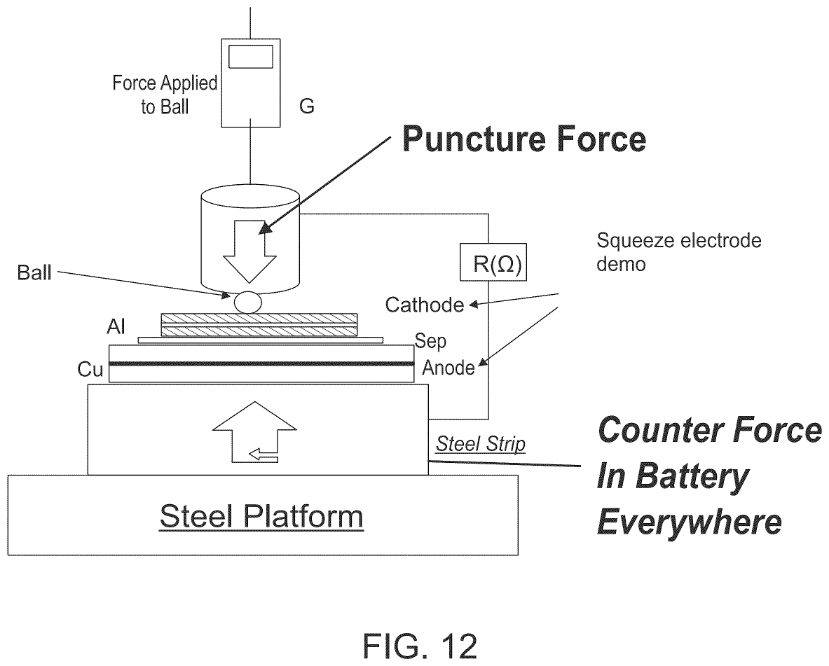

The inventors propose modifying the classic film puncture strength measurement to measure internal short resistance (ISR). To measure ISR, a squeeze electrode demo, e.g., a composite possibly preferably comprising an anode, a separator, and a cathode in that order. This squeeze electrode demo may be tested as shown in FIG. 12.

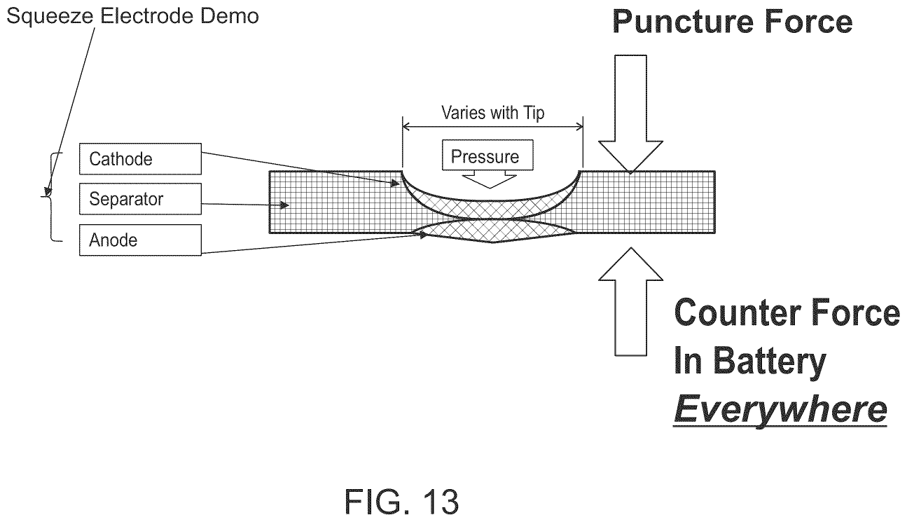

The squeeze electrode demo is not limited to anode/separator/cathode, and may possibly preferably be any one of the following non-limiting embodiments: cathode-material layer/separator/cathode-material layer; anode-material layer/separator/anode-material layer; anode-material layer/separator/cathode-material layer; Cu-foil/separator/Al-foil; Al-foil/separator/Cu-foil; Cu-foil/separator/Cu-foil; Cu-mesh/separator/Cu mesh; Al-mesh/separator/Al mesh; Cu particles/separator/Cu particles; and Al particles/separator/Al particles. As shown in FIG. 13, there is a direct counterforce to the puncture force when the squeeze electrode demo is used. This better simulates the conditions in the battery and should better predict performance in the battery.

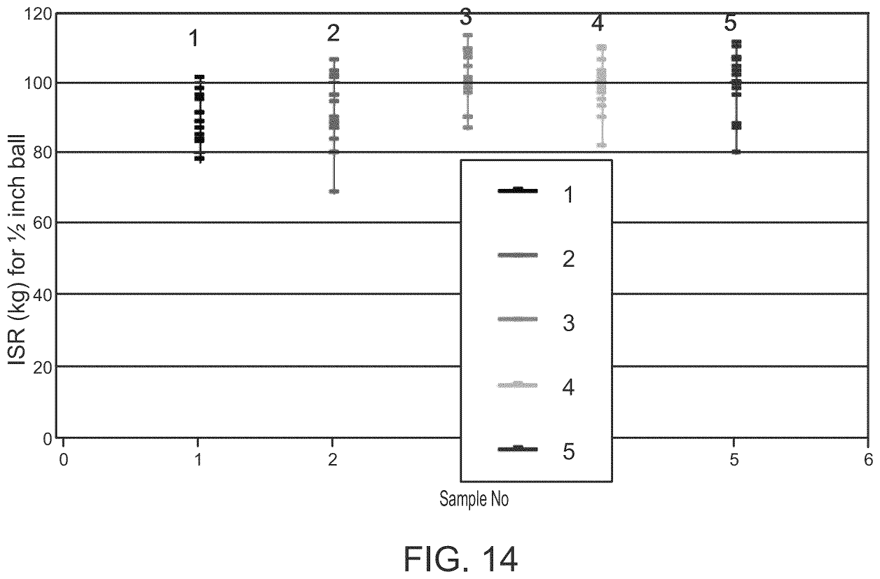

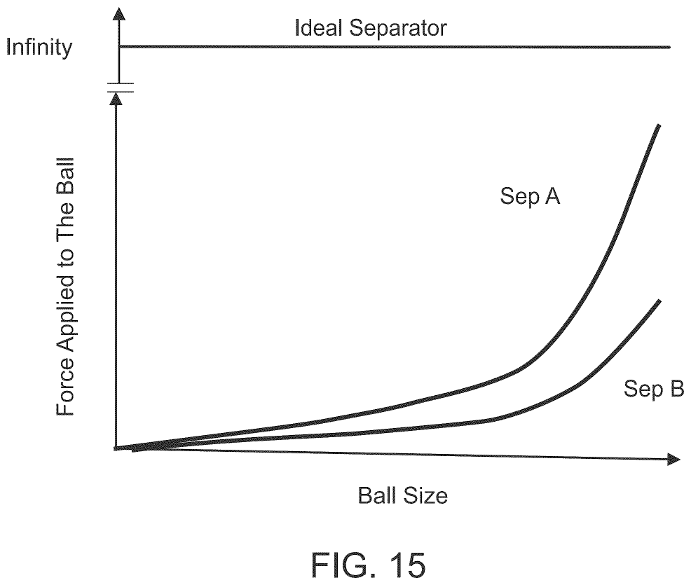

FIG. 14 is a graph of ISR (kg) measurements using a ½ inch ball and a setup as shown in FIG. 12. Measurements above 60 kg, above 80 kg, or above 100 kg may be typical. FIG. 15 is a graph showing the force applied to the ball as a function of ball size. For separators, as ball size increases, the force applied increases. For an ideal separator, the force applied to the ball would remain constant regardless of ball size.

### Measuring Tension Strength of the Separator Using a Puncture Strength Test

In some embodiments, the complex method may comprise measuring tension strength using a puncture strength test, e.g., classic film puncture strength measurement, as the only measurement step or one of many measurement steps. As explained above, the classic film puncture strength measurement is better for measuring the tension strength, instead of using it as a test to measure a separators resistance to shorts. Using the test to measure tension strength would be more appropriate.

### Separator

The separator to be tested is not so limited. In some embodiments, the separator may be a porous polymeric battery separator. The porous polymeric battery separator may be nanoporous, microporous, mesoporous, or macroporous. In some possibly preferred embodiments, the battery separator may be microporous

The polymer used to form the porous polymeric battery separator is not so limited. Any thermoplastic polymer may be used. In some embodiments, the porous polymeric battery separator is a porous polyolefin battery separator made from one or more polyolefins. In some preferred embodiments, the porous polyolefin battery separator may be made from polyethylene, polypropylene, or blends of polypropylene and/or polyethylene, or copolymers of polypropylene and polyethylene.

The separator may be a dry-process separator or a wet-process separator. Dry process separators and wet process separators exhibit distinct physical structures as explained at least in P. Arora, Z. Zhang, Battery Separators, Chem. Rev. 2004, 104, 4419-4462, which is incorporated herein in its entirety. As understood by one skilled in the art, a wet process separator is made by mixing hydrocarbon liquid, or some other low-molecular weight substance etc. with the polymer for processing. The mixture is then extruded into a sheet, the sheet is oriented into a machine direction (MD) or biaxially, and then the liquid is extracted using a solvent. A dry-process separator is not formed using solvent, liquids, oils, diluents, or the like. At least two categories of dry-process separators exist. One type includes particles, beta-nucleating agents, and the like that assist with the formation of pores. One well known dry-process separator of this type are beta-nucleated, biaxially-oriented polypropylene (BNBOPP) separators. In other dry-process separators, pores are formed by primarily stretching, and typically no particulates or pore former are added. One example of this type of dry-process separators includes those formed by the Celgard® dry-stretch method.

Commonly used separators may have a monolayer, bilayer, tri-layer, or multi-layer structure. Some commonly used separators are PP, PE, PP/PE/PP, PE/PP/PE, PP/PE, PP/PP/PP, or the like.

In addition to preventing electrode contact and allowing ionic transport between the electrodes, other desirable separator properties are a capability of being used on a high-speed winding machine and a good shutdown feature, which is essential for lithium-ion batteries. A quick shutdown speed and a long shutdown window over a range of temperatures may be preferred.

In some embodiments, the separators tested may be coated on one or both sides thereof. For example, they may include a polymeric coating, a ceramic coating, or combinations thereof.

### Ideal Separator

In another aspect, an ideal separator is described. The ideal separator has one or more of the following properties: low electrical resistance (ER)/o; approaching infinity; Ge approaching zero when the separator is dry or wet with electrolyte; low or no volume (higher Wh/l); low or no weight (high Wh/kg), anti-compression (z-performance, wet), super strong (XYZ direction strength for processing when dry and wet); all temperature stability (mechanical, electrical, and electro-chemical when wet and dry). An ideal separator may also be capable of experiencing infinite force when measuring internal short resistance (ISR) as described herein. See FIG. 15.

In accordance with at least selected embodiments, aspects or objects, there are disclosed or provided herein new or improved methods or devices for measuring battery separators that are more suitable for modern battery separators and may more accurately predict performance in the battery. Also disclosed are characteristics of an ideal separator that may be measured according to the new or improved methods herein. The ideal separator may comprise one of more of the following properties: low electrical resistance (ER)/o; approaching infinity; Ce approaching zero when the separator is dry or wet with electrolyte; low or no volume (higher Wh/l); low or no weight (high Wh/kg); anti-compression (z-performance, wet); super strong (XYZ direction strength for processing when dry and wet); all temperature stability (mechanical, electrical, and electro-chemical when wet and dry); and ability to apply infinite force when measuring ISR.

In summary, the battery separator separates the anode and the cathode, and provides ionic conduction when wet with electrolyte. There is no air flow through separators in the battery. Wetting, in a typical battery process, is a multi-phase vacuum process, without air. Classic puncture strength is a measure of the weakest tensile strength of the battery separator in any direction. The classic test is very different from real battery conditions, and very different from what is needed to prevent internal shorting that causes over 90% of safety incidents. Measuring ISR as described herein is a better test. The separator measurements described herein much better fit modern battery separators, true or actual battery conditions, and true separator performance.

1-22. (canceled)

23. A complex method of testing battery separator performance, comprising one or more of the following:
measuring the ionic conduction of the separator;
measuring the wettability of the separator under vacuum;
measuring the wettability of the separator while being squeezed; and,
measuring internal short resistance (ISR) of the separator.

24. The method of claim 23, wherein the ionic conduction of the separator is measured.

25. The method of claim 23, wherein the wettability of the separator is measured under vacuum.

26. The method of claim 23, wherein the ISR of the separator is measured.

27. The method of claim 26, wherein the ISR of the separator is measured in an x-direction of the separator.

28. The method of claim 26, wherein the ISR of the separator is measured in the y-direction of the separator.

29. The method of claim 26, wherein the ISR of the separator is measured in the z-direction.

30. The method of claim 26, wherein a squeeze electrode demo is used when testing the ISR of the separator, and the squeeze electrode demo is selected from the following:
cathode-material layer/separator/cathode-material layer;
anode-material layer/separator/anode-material layer;
anode-material layer/separator/cathode-material layer;
Cu-foil/separator/aluminum-foil;
Al-foil/separator/Cu-foil;
Cu-foil/separator/Cu-foil;
Cu-mesh/separator/Cu mesh;
Al-mesh/separator/Al mesh;
Cu particles/separator/Cu particles; and
Al-particles/separator/Al particles.

31. The method of claim 23, wherein the wettability of the separator is measured while being squeezed.

32. The method of claim 23, wherein the ionic conduction is measured, the wettability under vacuum is measured, and the internal short resistance is measured.

33. The method of claim 23, wherein the battery separator is a porous polymeric battery separator.

34. The method of claim 33, wherein the battery separator is a porous polyolefin battery separator.

35. The method of claim 33, wherein the battery separator is made by a dry-process.

36. The method of claim 35, wherein the battery separator is made by a dry-process that utilizes particles to form pores.

37. The method of claim 35, wherein the battery separator is made by a dry-process that does not utilize particles to form pores.

38. The method of claim 33, wherein the battery separator is made by a wet-process.

39. An ideal separator comprising one or more of the following properties:
low electrical resistance (ER)/σᵢ approaching infinity;
σₑ approaching zero when the separator is dry or wet with electrolyte;
low or no volume (higher Wh/l);
low or no weight (high Wh/kg);
anti-compression (z-performance, wet);
super strong (XYZ direction strength for processing when dry and wet);
all temperature stability (mechanical, electrical, and electro-chemical when wet and dry); and
ability to apply infinite force when measuring ISR.

40. The separator of claim 39, wherein the separator is a dry-process separator formed with the use of particles.

41. The separator of claim 39, wherein the separator is a dry-process separator formed without the use of particles.

42. The separator of claim 39, wherein the separator is a wet process separator.

43. A complex method of testing battery separator performance, comprising one or more of the following:
measuring the ionic conduction of the separator;
measuring the wettability of the separator under vacuum;
measuring the wettability of the separator being squeezed;
measuring tension strength using a puncture strength test; and,
measuring internal short resistance (ISR) of the separator.

44. A complex method of testing battery separator performance, comprising two or more of the following:
measuring the ionic conduction of the separator;
measuring the wettability of the separator under vacuum;
measuring the wettability of the separator being squeezed;
measuring tension strength using a puncture strength test; and,
measuring internal short resistance (ISR) of the separator.

45. A complex method of testing battery separator performance, comprising three or more of the following:
measuring the ionic conduction of the separator;
measuring the wettability of the separator under vacuum;
measuring the wettability of the separator being squeezed;
measuring tension strength using a puncture strength test; and,
measuring internal short resistance (ISR) of the separator.

46. A complex method of testing battery separator performance, comprising four or more of the following:
measuring the ionic conduction of the separator;
measuring the wettability of the separator under vacuum;
measuring the wettability of the separator being squeezed;
measuring tension strength using a puncture strength test; and,
measuring internal short resistance (ISR) of the separator.

47. A battery separator comprising two or more of the following properties:
low electrical resistance (ER)/σᵢ approaching infinity;
σₑ approaching zero when the separator is dry or wet with electrolyte;
low or no volume (higher Wh/l);
low or no weight (high Wh/kg);
anti-compression (z-performance, when wet);
super strong (XYZ direction strength for processing when dry and wet);
all temperature stability (mechanical, electrical, and electro-chemical when wet and dry); and
ability to apply infinite force when measuring ISR.

48. A battery separator comprising three or more of the following properties:
low electrical resistance (ER)/σᵢ approaching infinity;
σₑ approaching zero when the separator is dry or wet with electrolyte;
low or no volume (higher Wh/l);
low or no weight (high Wh/kg);
anti-compression (z-performance, when wet);
super strong (XYZ direction strength for processing when dry and wet);
all temperature stability (mechanical, electrical, and electro-chemical when wet and dry); and
ability to apply infinite force when measuring ISR.

49. A battery separator comprising four or more of the following properties:
low electrical resistance (ER)/σᵢ approaching infinity;
σₑ approaching zero when the separator is dry or wet with electrolyte;
low or no volume (higher Wh/l);
low or no weight (high Wh/kg);
anti-compression (z-performance, when wet);
super strong (XYZ direction strength for processing when dry and wet);
all temperature stability (mechanical, electrical, and electro-chemical when wet and dry); and
ability to apply infinite force when measuring ISR.
